(19) United States
(12) Patent Application Publication
(10) Pub. No.: US 2006/0187639 A1
(43) Pub. Date: Aug. 24, 2006

(54) Electronic component cooling and interface system

(75) Inventor: Charles C. Carswell, Weston, MA (US)

Correspondence Address: WEINGARTEN, SCHURGIN, GAGNEBIN & LEBOVICI LLP, TEN POST OFFICE SQUARE, BOSTON, MA, 02109, US

(73) Assignee: LYTRON, INC.

(21) Appl. No.: 11/063,911

(22) Filed: Feb. 23, 2005

(51) Int. Cl. H05K 7/20

(52) U.S. Cl. 361/699; 165/80.4

(57) ABSTRACT

A cooling system for a heat-generating component on a circuit board requires no fluid connections to be made or broken in order to install or remove the circuit board. In the cooling system, a heat collection device is mountable in heat transfer contact with a hot component on the circuit board. A heat removal device has a board-side device mountable to the circuit board and a complementary off-board device mountable off the circuit board. Fluid lines form a closed circulatory flow path between the heat collection device and the board-side device of the heat removal device. The board-side device and the off-board device are fastenable in heat transfer contact to transfer heat off the circuit board.

### CROSS REFERENCE TO RELATED APPLICATIONS

N/A

### STATEMENT REGARDING FEDERALLY SPONSORED RESEARCH OR DEVELOPMENT

N/A

### BACKGROUND OF THE INVENTION

Electronic components mounted on circuit boards generate heat that must be dissipated to assure proper functioning of the components. Air is typically used to cool the circuit board when the total power dissipated is low or when the power density is low. In high power applications, liquid can be used to provide significantly improved cooling, but at an added level of complexity. The liquid must be contained so it does not contact the components directly.

A way to contain cooling liquid is to use a liquid-cooled cold plate, typically made of copper, aluminum, or alloys of copper or aluminum. Channels within the cold plate distribute the cooling liquid throughout the plate, and inlets and outlets enable the liquid to enter and exit the cold plate. The cold plate is mated to the electronic circuit board that requires cooling. Electrical components on the circuit board are cooled by contact with the cold plate such that heat is transferred from the components to the cooling liquid. Fluid lines carry the heated fluid off the board to a heat exchanger or other heat sink to remove the heat from the fluid.

Because cold plates are co-mounted with the circuit boards, they must be removable when the circuit board is removed. Removing the cold plate requires severing the cooling liquid connections. When leaks occur in cold plates, typically they do not occur within the cold plate but rather where the plumbing connections are made to the plate.

### SUMMARY OF THE INVENTION

The present invention relates to a cooling system for an electronic component on a circuit board having improved reliability, because no fluid connections are required to install or remove the cooling system when installing or removing the circuit board.

The cooling system includes elements on a closed circulatory flow path mounted to the circuit board for installation or removal with the board. The cooling system elements include a heat collection device, such as a cold plate, that is mounted to a circuit board in heat transfer contact with one (or more) heat generating component(s) on the board, such as a computer chip or power device. Also, a heat removal device, such as a heat exchanger, is provided that includes a circuit board-side or component-side device mounted to the circuit board and that is in heat transfer contact with a complementary device mounted off the circuit board, such as on a cabinet in which the board is mounted. The interface between the board-side device and the off-board or cabinet-side device preferably has a toothed or other non-planar configuration to increase the surface area therebetween. Fluid lines are provided to form the circulatory flow path between the heat collection device and the board-side device of the heat removal device. A fastening device or mechanism is provided to bring the board-side device and the complementary off-board device of the heat removal device into heat transfer contact when the board is installed. No fluid connections in the circulatory flow path on the circuit board need to be completed or broken to install or remove the board.

### DESCRIPTION OF THE DRAWINGS

The invention will be more fully understood from the following detailed description taken in conjunction with the accompanying drawings in which:

FIG. 1 is a schematic illustration of a cooling system according to the present invention;

FIG. 2 is a schematic illustration of the heat collection device of the system of FIG. 1;

FIG. 3 is a schematic illustration of the heat removal device of the system of FIG. 1;

FIG. 4 is a schematic illustration of a further embodiment of a cooling system according to the present invention;

FIG. 5 is a schematic illustration of a still further embodiment of a cooling system; and

FIG. 6 is a schematic illustration of a still further embodiment of a cooling system.

### DETAILED DESCRIPTION OF THE INVENTION

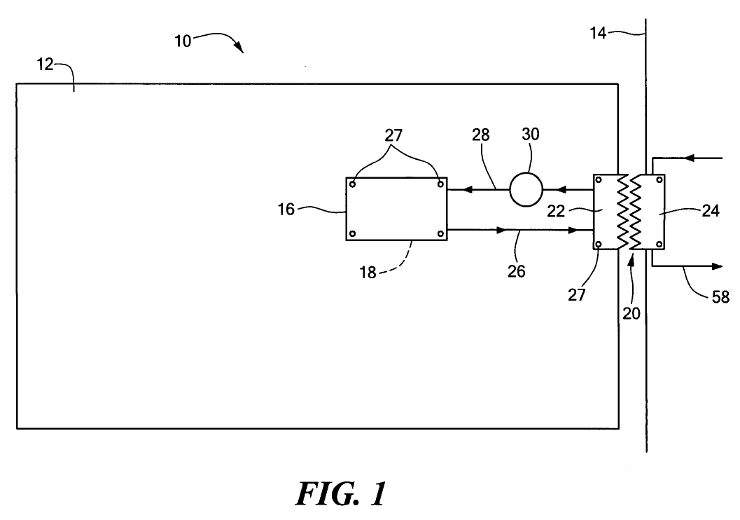

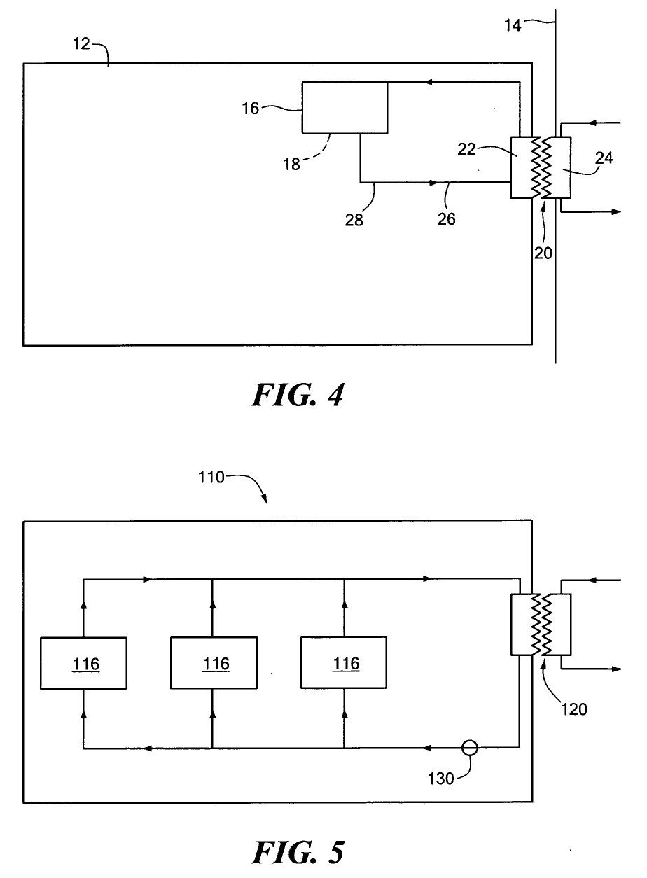

A cooling system 10 of the present invention is illustrated schematically in FIG. 1. The cooling system provides cooling for hot components such as a computer chip or power device on a circuit board 12 that is, for example, mounted to or within a cabinet 14. The cooling system incorporates a heat collection device 16 such as a cold plate, heat pipe, or spray cooling system to provide a heat transfer interface to one (or more) hot component(s) 18 (located beneath the device 16, indicated by a dashed lead line in FIG. 1). The cooling system also incorporates a heat removal device 20 such as a heat exchanger having one side 22 mounted to the circuit board 12 for removing heat from the circuit board. A complementary side 24 of the heat exchanger is mounted in or to the cabinet 14, so that heat is thereby transferred away from the circuit board 12. The two sides 22, 24 of the heat exchanger are removably fastened together in any suitable manner, such as with a fastening mechanism 25 (see FIG. 3). A cooling fluid, liquid, gas or air, circulates via fluid lines 26 that form a closed circulatory flow path 28 between the heat collection device 16 and the side 22 of the heat removal device 20 on the circuit board. A pump 30 may be located on the circulatory path 28 to move the cooling fluid along the path. In an alternative embodiment, illustrated in FIG. 4, the cooling fluid may circulate without a pump.

The heat collection device 16 and the board-side device 22 of the heat removal device 20 of the board cooling system are fastened to the circuit board in any suitable manner, such as with screws 27 or another fastening device or mechanism. The fluid lines 26 may also, if desired, be fastened to the board in any suitable manner. These elements of the board cooling system do not need to be removed from the board to remove the board from the cabinet. No fluid connections in the circulatory flow path 28 on the circuit board need to be made during installation of the board or need to be openable or removable from the cooling system to remove the board. The circulatory flow path may, if desired, be formed during manufacture with permanent fluid connections. In this manner, the likelihood of leakage in the cooling system is significantly minimized and reliability is enhanced.

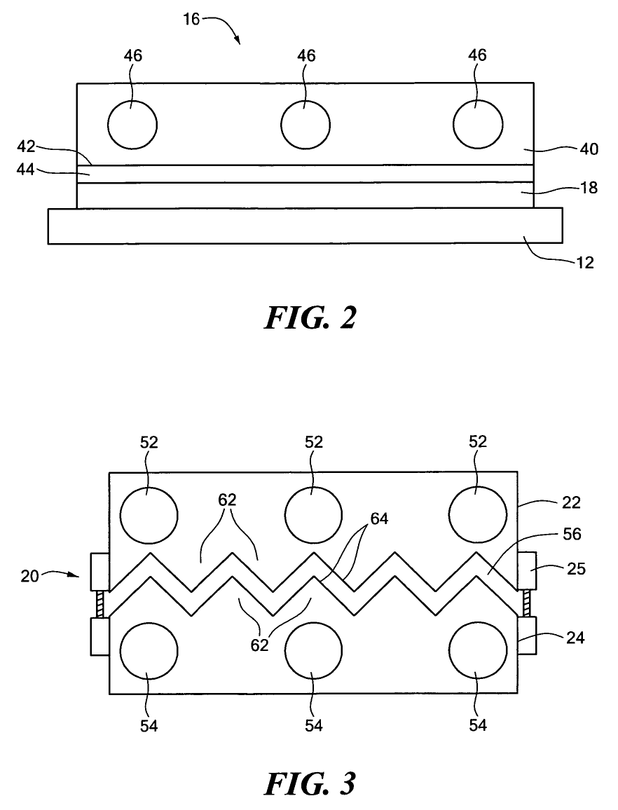

The heat collection device 16 is illustrated more particularly as a cold plate 40 in FIG. 2. The hot component 18 is mounted on the circuit board 12. The cold plate has a flat lower surface 42 that is placed adjacent the hot component. If the component to be cooled is not flat enough to allow good heat transfer, a heat transmissive thermal interface material 44 may be interposed between the component 18 and the flat surface 42 of the cold plate 40, as illustrated in FIG. 2. Interface materials that exhibit varying thermal transmissivity characteristics as well as other characteristics such as compressibility and electrical insulation are readily commercially available. To assure good contact between the component 18 to be cooled and the cold plate 40, the thermal interface material 44 may be compressed therebetween, such as by a clamping mechanism. The clamping mechanism may be the same as the fastening mechanism that fastens the cold plate to the board or may be separate therefrom.

The cold plate 40 may be made of aluminum, copper, alloys of aluminum or copper, or other suitable heat transmissive materials, as would be known in the art. The cooling fluid enters the cold plate at an entry temperature lower than that of the hot component and circulates through channels 46 in the cold plate. Heat from the hot component is thereby transferred through the material of the cold plate to the cooling fluid. The cooling fluid exits the cold plate for flow to the heat removal device 20. The cold plate may be fastened to the circuit board in any suitable manner, such as with screws 27 or another fastening device or mechanism. Preferably, the fastening device or mechanism provides a clamping force to the cold plate to ensure good contact between the cold plate and the hot component. Alternatively, the cold plate fluid may assume the heat through a spray cooling/jet impingement system. In this embodiment, fluid is sprayed through nozzles contained in the cold plate. The fluid absorbs the heat that has been transferred through the material of the cold plate.

Any suitable cooling fluid can be used in the circulatory path on the board. Water has an excellent heat transfer function and is readily available. An ethylene glycol/water mixture is also generally suitable. High dielectric fluids, such as fluorocarbons, can alternatively be used. Fluorocarbons are less damaging than water to the electronic components if a leak occurs, but have a less advantageous heat transfer function and are more expensive.

The heat removal device 20 is illustrated as a heat exchanger in FIGS. 1 and 3. The board-side or component-side device 22 of the heat exchanger is mounted to the circuit board 12 and forms part of the circulatory path mounted on the circuit board. The cooling fluid enters the board-side device and passes through channels 52 in the device. The cabinet-side or off-board device 24 of the heat exchanger is mounted off the board, such as to the cabinet 14. A second fluid circulates through channels 54 in the cabinet-side device. Heat from the board cooling fluid is transferred across the interface 56 between the board-side device 22 and the cabinet-side device 24 to the second cooling fluid.

The fluid in the cabinet-side device can be a liquid or air or other gas. Liquid cooling allows the heat to be removed from the cabinet and not added to the building air heat load, which improves overall facility efficiency. Preferably, water is used as the cooling liquid, and a water line 58 is provided from the facility's water supply to the cabinet-side device. Other cooling fluids, such an as ethylene glycol/water mixture, can be used if desired.

The interface 56 between the two sides 22, 24 of the heat exchanger is preferably configured to increase the contact surface area. For example, angled teeth 62 can be provided on the contacting surfaces 64 of each side. It will be appreciated that the contacting surfaces can take other configurations, such as a flat or curved surface or another non-planar geometry. In FIGS. 1 and 3, the interface is illustrated in an opened configuration, with a separation between the sides. In operation, the two sides 22, 24 are fastened together, such as with a screw fastening device 25 or another mechanism, so that the surfaces are in contact. The two sides can be clamped or otherwise fastened together to increase the pressure between the two sides, to further enhance the heat transfer. There may be thermal interface material between the two contacting surfaces. If the circuit board needs to be removed from the cabinet, the two sides of the heat exchanger are unfastened. The cooling system circuit on the board remains intact and can be removed with the board without breaking the fluid lines on the flow path 28.

It will be appreciated that the component-side device 22 does not need to be mounted or otherwise attached to the circuit board in all cases. For example, the component-side device may be fastened only to the off-board device 24, or to both the off-board device and to the cabinet 14. In this case, to remove the circuit board, the component-side device can be detached from the off-board device, and the cabinet if necessary, for removal with the circuit board, so that the flow path 28 remains unbroken.

In one exemplary embodiment, the cooling system may be a two-phase system incorporating an evaporative cold plate as the heat collection device 16 and a condenser as the heat removal device 20. Cooling fluid in liquid phase enters the cold plate. Heat from the hot component is transferred to the cold plate containing the flowing liquid, boiling the liquid. The latent heat of vaporization transforms the liquid to gas with no temperature change except for that caused by the pressure drop. This provides a uniform temperature interface across the hot device. The cooling fluid, a gas or liquid/gas mixture, is delivered to the condenser mounted to the board. The condenser is in contact with the off-board device mounted to the cabinet. The board cooling fluid is fully condensed as it leaves the condenser and is delivered back to the hot component. The cooling system is capable of providing excellent heat transfer at nearly constant interface temperature to a hot component.

As shown in FIG. 1, a sealed pump 30 may be used to move the fluid. The flow rate can be very low because the heat of vaporization is large compared to the specific heat of a fluid. This keeps the pump flow and power requirement low. Pressure loss in the system comes only from the flow. No expansion pressure drop is necessary. The cooling efficiency is very high compared to the power requirement. A reservoir or accumulator may be provided with the pumped system if necessary or desired, as can be readily determined by those of skill in the art.

In another embodiment, a single-phase system can be used, in which the cooling fluid does not undergo a phase change at the cold plate. The choice of system depends on the parameters of the particular circuit board to be cooled, and can be readily determined by those of skill in the art. FIG. 4 illustrates an embodiment similar to FIG. 1; however, this system does not use a pump. The fluid is moved through the system via an internal wicking structure, such as a screen, grooves, felt, or sintered powder. The heat collection device and the heat removal device may constitute a heat pipe.

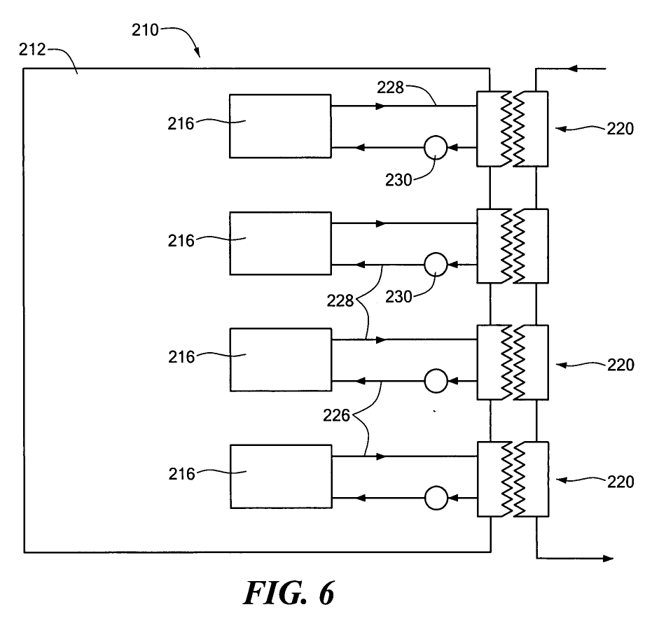

FIG. 5 illustrates an embodiment of a cooling system 110 in which a plurality of heat collection devices 116 is employed in parallel with the heat removal device 120. In this manner, a number of hot components on the circuit board can be cooled. FIG. 6 illustrates a further embodiment of a cooling system 210 in which multiple cooling circuits 228 are provided on one circuit board 212. Each circuit employs a heat removal device 216 for an associated hot component on the board, cooling lines 226, a pump 230 (optional, as noted above), and a heat removal device 220 for removing the heat from the board. In this manner also, a number of hot components on the circuit board can be cooled.

The cooling system has been particularly described in conjunction with a component mounted on a circuit board; however, the cooling system may be used with or as components not specifically mounted on a circuit board, for example, as an electrode in a laser system. The invention is not to be limited by what has been particularly shown and described, except as indicated by the appended claims.

What is claimed is:

1. A cooling system for a circuit board having at least one heat generating component mounted thereon, comprising:
a heat collection device mountable to a circuit board in heat transfer contact with a heat generating component mounted on the circuit board;
a heat removal device comprising a board-side device mountable to the circuit board and a complementary off-board device mountable off the circuit board, the board-side device and the off-board device fastenable in heat transfer contact to transfer heat off the circuit board;
fluid lines forming a closed circulatory flow path between the heat collection device and the board-side device of the heat removal device;
a board cooling fluid disposed for circulation within the closed circulatory flow path on the circuit board; and
an off-board cooling fluid disposed for circulation through the off-board device.

2. The system of claim 1, wherein the board cooling fluid comprises water.

3. The system of claim 1, wherein the board cooling fluid comprises water, an ethylene glycol/water mixture, or a fluorocarbon or other fluid or gas.

4. The system of claim 1, wherein the off-board cooling fluid comprises water.

5. The system of claim 1, wherein the off-board cooling fluid comprises water, an ethylene glycol/water mixture, or a fluorocarbon or other fluid or gas.

6. The system of claim 1, wherein the heat collection device comprises a cold plate.

7. The system of claim 6, wherein the heat collection device further comprises a thermal interface material beneath the cold plate.

8. The system of claim 1, wherein the heat collection device comprises a spray cooling system.

9. The system of claim 1, wherein the heat collection device comprises an evaporator.

10. The system of claim 1, wherein the heat collection device and the heat removal device comprise a heat pipe.

11. The system of claim 1, wherein the heat removal device comprises a heat exchanger.

12. The system of claim 1, wherein the heat removal device includes a condenser.

13. The system of claim 1, wherein an interface between the board-side device and the off-board device comprises a toothed surface.

14. The system of claim 1, wherein an interface between the board-side device and the off-board device comprises a curved surface.

15. The system of claim 1, wherein an interface between the board-side device and the off-board device comprises a flat surface.

16. The system of claim 1, wherein an interface between the board-side device and the off-board device comprises a non-planar.

17. The system of claim 1, wherein the heat removal device further comprises a thermal interface material between the board-side device and the off-board device.

18. The system of claim 1, wherein the cooling system comprises a two-phase fluid system.

19. The system of claim 1, wherein the cooling system comprises a single-phase fluid system.

20. The system of claim 1, further comprising a pump in the fluid lines forming the closed circulatory flow path.

21. The system of claim 1, further comprising additional heat collection devices in the closed circulatory flow path in parallel with the heat collection device and the board-side device of the heat removal device.

22. The system of claim 1, further comprising an additional closed circulatory flow path between an additional heat collection device and an additional board-side device of an additional heat collection device.

23. A circuit board cooling system comprising:
a circuit board, at least one heat generating component mounted on the circuit board; and
the cooling system of claim 1, wherein the heat collection device and the board-side device are mounted to the circuit board, the heat collection device in heat transfer contact with the heat generating component.

24. A cooling system for a heat-generating component, comprising:
a heat collection device in heat transfer contact with a heat-generating component;
a heat removal device comprising:
a component-side device,
a complementary device,
an interface comprising a non-planar surface between the component-side device and the complementary device, and
a fastening mechanism operative to fasten the component-side device and the complementary device in heat transfer contact to transfer heat from the component-side device to the complementary device;
fluid lines forming a closed circulatory flow path between the heat collection device and the component-side device of the heat removal device;
a component cooling fluid disposed for circulation within the closed circulatory flow path; and
a cooling fluid disposed for circulation through the complementary device.

25. The system of claim 24, wherein the non-planar surface comprises a toothed surface.

26. The system of claim 24, wherein the non-planar surface comprises a curved surface.

27. The system of claim 24, wherein the non-planar surface comprises a curved surface.

28. The system of claim 24, wherein the component cooling fluid comprises water, an ethylene glycol/water mixture, or a fluorocarbon.

29. The system of claim 24, wherein the cooling fluid through the complementary device comprises water, an ethylene glycol/water mixture, or a fluorocarbon.

30. The system of claim 24, wherein the heat collection device comprises a cold plate.

31. The system of claim 24, wherein the heat collection device further comprises an electrode, the electrode further comprising the heat-generating component.

32. The system of claim 24, wherein the heat collection device comprises an evaporator.

33. The system of claim 24, wherein the heat removal device includes a condenser.

34. The system of claim 24, wherein the heat collection device further comprises a thermal interface material between the component-side device and the complementary device.

35. The system of claim 24, wherein the heat collection device is mountable to a circuit board.

36. The system of claim 24, wherein the component-side device is mountable to a circuit board.

37. The system of claim 24, wherein the heat collection device is mountable to a circuit board and the component-side device is mountable to a support off the circuit board.
